(19) United States
(12) Patent Application Publication
(10) Pub. No.: US 2015/0255365 A1
(43) Pub. Date: Sep. 10, 2015

(54) MICROELECTRONIC PACKAGE PLATE WITH EDGE RECESSES FOR IMPROVED ALIGNMENT

(71) Applicant: NVIDIA CORPORATION, Santa Clara, CA (US)

(72) Inventors: Yeong J. LEE, Santa Clara, CA (US); Ernie OPINIANO, San Jose, CA (US)

(73) Assignee: NVIDIA CORPORATION, Santa Clara, CA (US)

(21) Appl. No.: 14/198,194

(22) Filed: Mar. 5, 2014

(51) Int. Cl. H01L 23/367; H01L 23/544

(52) U.S. Cl. CPC H01L 23/3675; H01L 23/544

(57) ABSTRACT

A microelectronic package includes a package substrate with at least one semiconductor die mounted thereon and a plate coupled to the package substrate. The plate is configured with a first recess formed in a first edge of the plate and a second recess formed in a second edge of the plate wherein the first edge and the second edge are formed on opposing sides of the plate. One advantage of the above-described embodiments is that a stiffener plate or heat spreader that is sized to cover most or all of the periphery of a package substrate can be coupled to the package substrate without causing alignment issues in subsequent fabrication processes.

### BACKGROUND OF THE INVENTION

1. Field of the Invention

Embodiments of the present invention relate generally to integrated circuit chip packaging and, more specifically, to a microelectronic package plate with edge recesses for improved alignment.

2. Description of the Related Art

In the packaging of integrated circuits (ICs), a stiffener or heat spreader is often included in the IC package to enhance the mechanical rigidity of the package and/or to improve conductive heat transfer from one or more IC chips contained in the package. Both stiffeners and heat spreaders are formed from a metal plate that is coupled to the package substrate on which one or more ICs, capacitors, and other devices are mounted. Precise placement of the stiffener or heat spreader on the package substrate is necessary to prevent “overhang,” in which misalignment between the package substrate and the stiffener or heat spreader is so great that one or more portions of the stiffener or heat spreader extend beyond an edge of the package substrate.

The occurrence of stiffener or heat spreader overhang can adversely affect the alignment on subsequent steps in the fabrication of an IC package, thereby increasing package defect rate and/or reducing the reliability of IC packages that are not rejected as being defective. This is because the overhang of the stiffener or heat spreader greatly influences the alignment accuracy of the package substrate in major assembly processes such as mounting solder balls on an IC package and testing of a completed IC package. When mounting solder balls, misalignment of the package substrate due to stiffener or heat spreader overhang may result in solder ball placement offset from pads. In automated testing, misalignment of the package substrate due to stiffener or heat spreader overhang may result in damage to the solder balls, sometimes referred to as “ball chop.”

As the foregoing illustrates, there is a need in the art for an IC package that can be fabricated that even an overhang stiffener or heat spreader, such overhang will not affect the accuracy of package substrate alignment.

### SUMMARY OF THE INVENTION

Embodiments of the present invention set forth a microelectronic package a package substrate with at least one semiconductor die mounted thereon and a plate coupled to the package substrate. The plate is configured with a first recess formed in a first edge and a second recess formed in a second edge, where the first edge and the second edge are formed on opposing sides of the plate.

One advantage of the above-described embodiments is that a stiffener plate or heat spreader that is sized to cover most or all of the periphery of a package substrate can be coupled to the package substrate without causing alignment issues in subsequent fabrication processes. In this way, microelectronic package stiffness can be improved without affecting alignment of the microelectronic package is some fabrication steps. Consequently, a microelectronic package can be fabricated with greater stiffness and without increasing defectivity or reliability.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a microelectronic package, according to one embodiment of the present invention.

FIG. 2 is a schematic cross-sectional view of a microelectronic package, according to another embodiment of the present invention.

FIG. 3 is a schematic plan view of the microelectronic package of FIG. 2, according to one embodiment of the present invention.

FIG. 4A is a schematic cross-sectional view of the microelectronic package of FIG. 3 taken at section A-A, according to another embodiment of the present invention.

FIG. 4B is a schematic cross-sectional view of a prior art microelectronic package that does not include recesses formed on a plate.

FIG. 5 illustrates a computing device in which various embodiments of the present invention can be implemented.

In some embodiments, recesses 136 are formed closer to corners 302 of plate 230 than to an edge center point 303 of plate 230. Such a configuration of recesses 136 is implemented to correspond to locations of alignment tool components 301, which generally are so positioned in order to facilitate more accurate positioning of microelectronic package 200.

For clarity, identical reference numbers have been used, where applicable, to designate identical elements that are common between figures. It is contemplated that features of one embodiment may be incorporated in other embodiments without further recitation.

### DETAILED DESCRIPTION

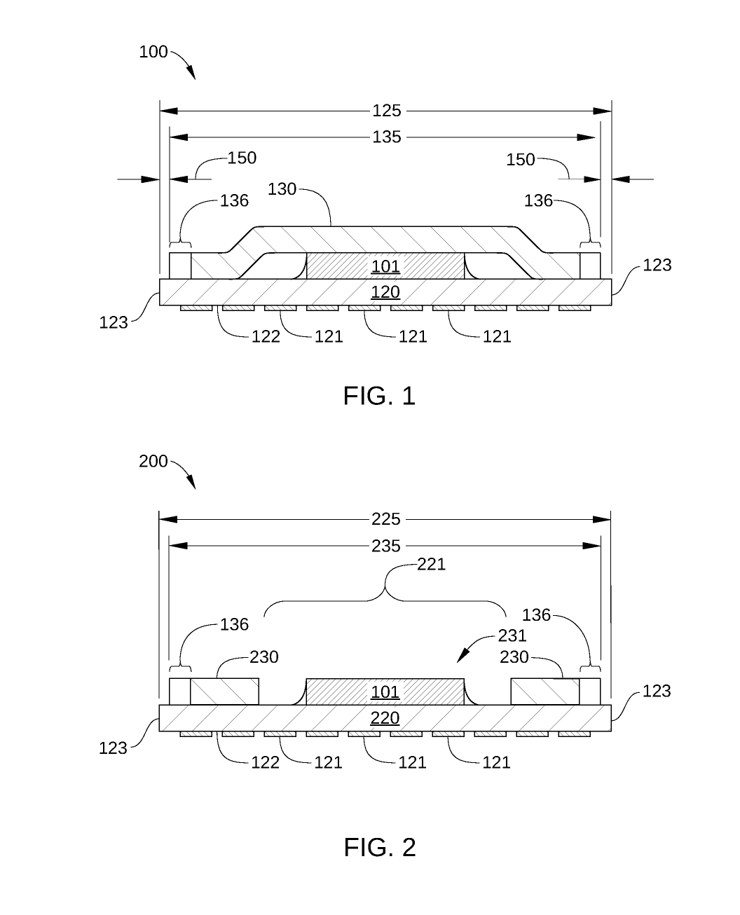

FIG. 1 is a schematic cross-sectional view of a microelectronic package 100, according to one embodiment of the present invention. As shown, microelectronic package 100 includes one or more integrated circuit (IC) chips 101, a package substrate 120, and a plate 130. Microelectronic package 100 is configured to electrically and mechanically connect IC chip 101 and any other ICs mounted on package substrate 120 to a printed circuit board or other mounting substrate (not shown) external to microelectronic package 100. In addition, microelectronic package 100 protects IC chip 101 from ambient moisture and other contamination and minimizes mechanical shock and stress thereon.

IC chip 101 is a semiconductor chip, such as a central processing unit (CPU), a graphics processing unit (GPU), an application processor or other logic device, a memory chip, a global positioning system (GPS) chip, a radio frequency (RF) transceiver chip, a Wi-Fi chip, a system-on-chip, or any semiconductor chip that is suitable for mounting on package substrate 120. Thus, IC chip 101 may be any IC chip or chips that may benefit from being assembled together in a single microelectronic package. In some embodiments, IC chip 101 is a logic chip, such as a CPU or GPU, and one or more additional IC chips (not shown for clarity) mounted on package substrate 120 are memory chips associated with IC chip 101. IC chip 101 is mounted on package substrate 120, and may be electrically coupled thereto using solder microbumps or any other technically feasible approach. An underfill material and/or over-molding may be used to protect the solder microbumps or other electrical connections between IC chip 101 and package substrate 120.

Package substrate 120 acts as a support structure in microelectronic package 100 that also provides electrical connections between IC chip 101 and pads 121 formed on bottom surface 122 of package substrate 120. Thus, package substrate 120 is a somewhat rigid substrate on which IC 101 is mounted that provides microelectronic package 100 with structural rigidity. In some embodiments, package substrate 120 is an organic laminate substrate and is composed of a stack of insulative layers or laminates that are built up on the top and bottom surfaces of a core layer. Pads 121 are electrically conductive pads configured for the placement of solder balls on microelectronic package 100 that provide electrical connections between microelectronic package 100 and a printed circuit board or other mounting substrate external to microelectronic package 100.

Plate 130 is coupled to package substrate 120 as shown, for example with an adhesive, and is configured to provide stiffening support to package substrate 120. Thus, when package substrate 120 is a thin-core or coreless substrate, plate 130 can greatly improve the overall structural rigidity of microelectronic package 100 with respect to bending, torsion, and especially the warping that may otherwise occur as IC 101 generates heat during operation. Furthermore, even with more rigid package substrates, plate 130 can significantly improve the rigidity of microelectronic package 100.

Ideally, plate 130 extends as close as practicable to each edge 123 of package substrate 120, to increase stiffness of microelectronic package 100. In other words, plate 130 is fabricated with a width 135 that is as close as possible to a width 125 of package substrate 120, without actually being greater than width 125. In this way, rigidity of microelectronic package 100 is maximized. However, given the limits of the placement accuracy of plate 130, the closer width 135 is to width 125, the more likely overhang may result when plate 130 is coupled to package substrate 120. For example, if plate 130 may be formed with a width 135 that is 0.10 mm less than width 125 of package substrate 120, so that gap 150 is ideally 0.05 mm on each side of package substrate 120. However, when the placement accuracy of plate 130 is significantly greater than gap 150, for example on the order of about 0.20 mm, overhang of plate 130 beyond one of edges 123 can occur on the order of about 0.15 mm, which is highly undesirable for subsequent fabrication processes.

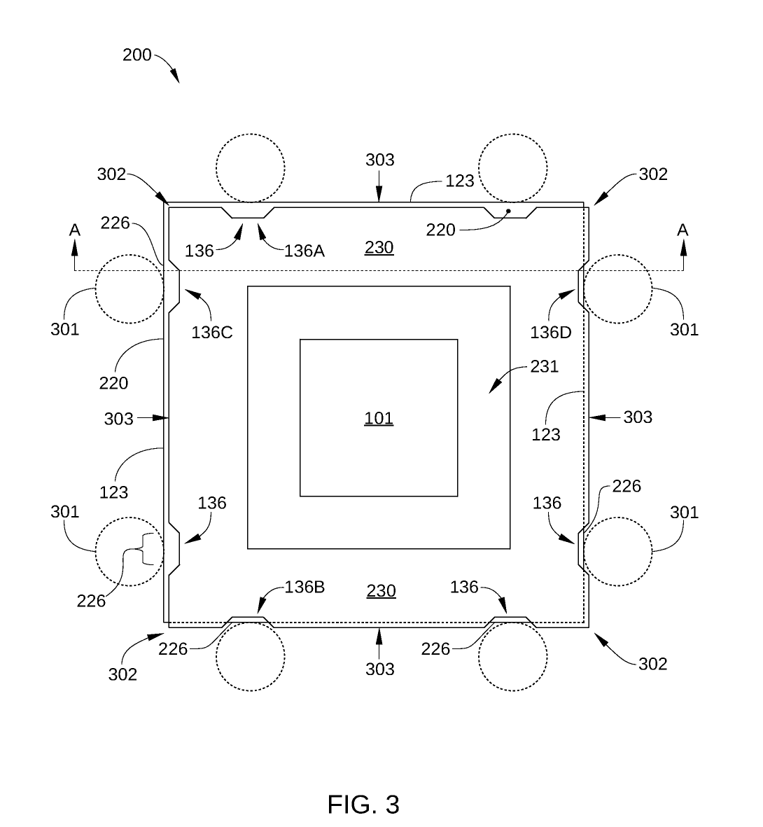

According to embodiments of the present invention, plate 130 is configured with one or more pairs of recesses 136 that correspond to alignment surfaces of package substrate 120. These alignment surfaces of package substrate 120 are generally located on edges 123 of package substrate 120, and are configured to contact one or more alignment tool surfaces as part of testing or package assembly processes. Recesses 136 allow plate 130 to have a width 135 that can be equal to or even greater than width 125 of package substrate 120 without adversely affecting subsequent fabrication processes that rely on precise positioning of package substrate 120. For example, when mounting solder balls on pads 121 or applying test pins to solder balls attached to pads 121, precise positioning of package substrate 120 and, consequently, microelectronic package 100, prevent solder ball misalignment and/or ball chop. Recesses 136 are described in greater detail below in conjunction with FIG. 3.

In the embodiment illustrated in FIG. 1, plate 130 is also configured as a heat spreader, which is thermally coupled to IC chip 101 to enhance transmission of heat generated by IC chip 101. In such embodiments, plate 130 may be formed from a single piece of metal having a relatively high thermal conductivity, such as a stamped copper or aluminum plate. Suitable materials for plate 130 include copper, aluminum, or any other metal having suitable thermal conductivity. For example, in some embodiments, plate 130 may be a structurally rigid material having a thermal conductivity that is at least equal to the thermal conductivity of aluminum, i.e., at least about 230 W m⁻¹ K⁻¹. In some embodiments, plate 130 is thermally coupled to IC chip 101 by being placed in thermal contact therewith, which includes direct physical contact or via a thermal interface material (TIM) disposed between IC chip 101 and plate 130. The TIM may be a thin layer of thermally conductive material configured to maximize conductive heat transfer between IC chip 101 and plate 130. Suitable materials for the TIM include thermally conductive gels, thermal greases, solders, or a thermally conductive sheet, such as a mechanically compressible gap pad. In some embodiments, such as when microelectronic package 100 is a multi-chip module, plate 130 may be in thermal contact with multiple IC chips and not just with IC chip 101.

In some embodiments, a plate of a microelectronic package is not configured as a heat spreader and, therefore, is not disposed in thermal contact with IC chip 101 and/or other chips that are mounted on a packaging substrate. One such embodiment is illustrated in FIG. 2 and described below.

FIG. 2 is a schematic cross-sectional view of a microelectronic package 200, according to another embodiment of the present invention. As shown, microelectronic package 200 includes IC chip 101, a package substrate 220, and a plate 230. Microelectronic package 200 is substantially similar in configuration to microelectronic package 100 of FIG. 1, except that plate 230 of microelectronic package 200 is not in thermal contact with IC chip 101. Instead, plate 230 includes a central opening 231 that corresponds to a keep out area 221 of package substrate 220. Keep out area 221 of package substrate 220 is generally a central region of package substrate 220, in which one or more IC chips 101, passive devices such as capacitors, and other surface-mounted devices are disposed. To enhance structural rigidity of microelectronic package 200, plate 230 is coupled to the periphery of package substrate 220, but outside of keep out area 221. In some embodiments, plate 230 may be formed with a width 135 that is on the order of 0.10 mm less than a width 225 of package substrate 220, so that gap 150 is ideally 0.05 mm on each side of package substrate 120.

FIG. 3 is a schematic plan view of microelectronic package 200, according to one embodiment of the present invention. As shown, plate 230 is substantially aligned with and coupled to package substrate 220, and includes recesses 136 formed in the edges of plate 230. However, due to the limits of the placement accuracy of plate 230, plate 230 is generally not perfectly aligned with package substrate 220, and in some cases overlaps one or more of edges 123 of package substrate 220. In FIG. 3, edges 123 overlapped by plate 230 are shown as dashed lines.

As noted above, recesses 136 are positioned to substantially correspond to the locations of alignment surfaces 226 of package substrate 220. Alignment surfaces 226 are configured to contact alignment tool components during alignment-sensitive processes, such as automated package testing and solder ball assembly. Because the edges of package substrate 220 are generally manufactured to a high tolerance, for example on the order of a few tenths of a millimeter, the edges of package substrate 220 can be used to precisely align microelectronic package 200 during alignment-sensitive processes. For reference, alignment tool components 301 (dashed lines) are shown positioned in contact with alignment surfaces 226 of package substrate 220. While illustrated in FIG. 3 as pins having circular cross section, each of alignment tool components 301 may be any technically feasible alignment tool component including a planar surface, a rectangular or other-shaped finger, and the like.

The exact geometry of recesses 136, e.g., depth and width, can be selected based a variety of factors, including the size and shape of alignment tool components 301 that contact alignment surfaces 226 and the placement accuracy of plate 230 with respect to package substrate 220. For example, in situations in which the placement accuracy of plate 230 is relatively low, recessed 136 can be configured with greater depth (i.e., away from edge 123) to accommodate the greater possible range of position of plate with respect to package substrate 220. One of skill in the art can readily determine a suitable geometry for recesses 136 for any particular configuration of microelectronic package 200.

Generally, recesses 136 are formed in pairs, so that one recess 136 of a particular pair is located on one side of plate 230 and the other recess 136 of the pair is located on an opposing side of plate 230. For example, as shown in FIG. 3, recess 136A is disposed opposite recess 136B, and recess 136C is disposed opposite recess 136D. Such an arrangement of recesses in pairs 136 disposed on opposite sides of plate 230 generally corresponds to the configuration of alignment tool components used to precisely align microelectronic package 200 in some fabrication processes.

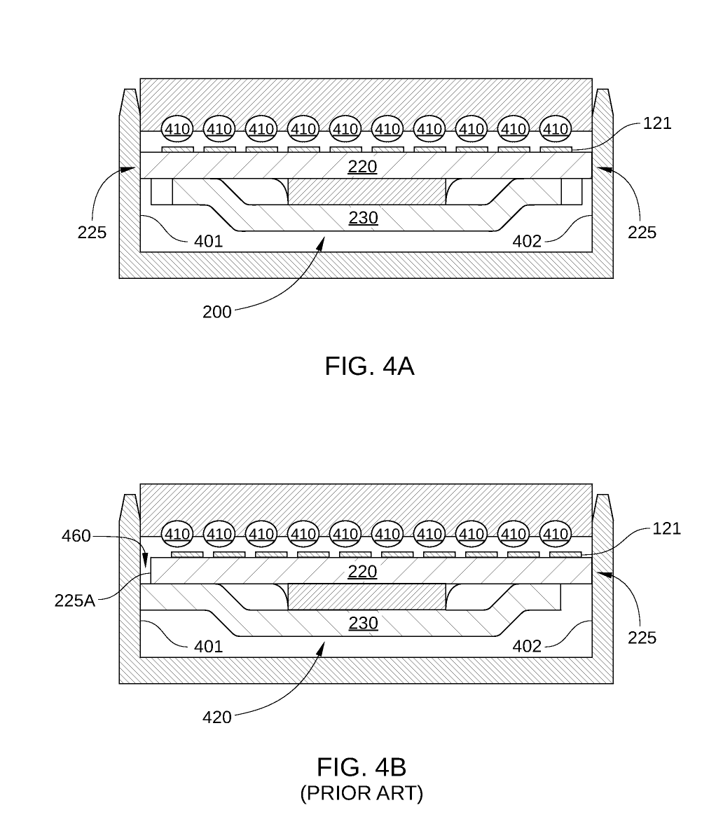

As already noted, recesses 136 are positioned to correspond to the location of alignment surfaces 226. Consequently, recesses 136 are also positioned to correspond to the location of alignment tool components 301, so that overhang of plate 230 beyond an edge 123 of package substrate 220 does result in contact between plate 230 and any of alignment tool components 301. In this way, recesses 136 ensure that significant misalignment of plate 230 with package substrate 220 does not affect the accuracy of positioning microelectronic package 200 during subsequent alignment-sensitive processes, such as solder ball assembly or automated testing. Thus, plate 230 can be configured with a width 235 that is substantially equal to width 225 of package substrate 220, thereby maximizing stiffness of microelectronic package 200. For clarity, width 225 and width 235 are shown in FIG. 2. In some embodiments, plate 230 can be configured with a width 235 that is equal to or slightly greater than width 225 of package substrate 220, thereby ensuring that plate 230 contacts the entire periphery of package substrate 230. The benefits of recesses 136 are further described below in conjunction with FIGS. 4A and 4B.

In some embodiments, when microelectronic package 200 is square or rectangular in configuration, at least one alignment tool component 301 for each side of microelectronic package 200 is used to contact and position microelectronic package 200 during certain fabrication processes. Consequently, in such embodiments, at least one recess 136 is disposed on each side of plate 230, where each recess 136 corresponds to the location of one of the alignment tool components used to align microelectronic package 200. In such embodiments, plate 230 is configured with a recess 136 for each and every alignment tool component used to align microelectronic package 200 during fabrication thereof. Furthermore, in some embodiments, some of recesses 136 are positioned to correspond to the location of alignment tool components 301 used to align microelectronic package 200 during one fabrication process (for example, solder ball mounting), and other of recesses 136 are positioned to correspond to the location of alignment tool components 301 used to align microelectronic package 200 during a different fabrication process (for example, automated testing of microelectronic package 200).

FIG. 4A is a schematic cross-sectional view of microelectronic package 200 of FIG. 3 taken at section A-A in FIG. 3, according to another embodiment of the present invention. For reference, FIG. 4A further illustrates a first alignment tool surface 401 and a second alignment tool surface 402, that together are used to position microelectronic package 200 for an alignment-sensitive process, such as automated testing or solder ball assembly. In FIG. 4A a solder ball assembly process is depicted, but first alignment tool surface 401 and second alignment tool surface 402 may be used in a similar manner for other alignment-sensitive processes as well.

As shown, microelectronic package 200 is precisely positioned with respect to solder balls 410 since first alignment tool surface 401 contacts one of alignment surfaces 226 of package substrate 220 and second alignment tool surface 402 contacts an opposing alignment surface 226 of substrate 220. In this way, solder balls 410 are suitably aligned with pads 121, even if plate 230 is significantly misaligned with package substrate 220.

FIG. 4B is a schematic cross-sectional view of a prior art microelectronic package 420 that does not include recesses 136 formed on plate 230. In other respects, microelectronic package 420 is substantially similar to microelectronic package 200. Because microelectronic package 420 does not include recesses 136 formed in plate 230, any misalignment of plate 230 that causes overhang 460 at one or more edges of package substrate 220 directly impacts positioning of microelectronic package 420 when in contact with first alignment tool surface 401 and second alignment tool surface 402. In FIG. 4B, overhang 460 results in first alignment tool surface 401 contacting plate 230 instead of alignment surface 226A of package substrate 220. As shown, such misalignment causes significant solder ball offset with respect to pads 121, which can cause outright rejection of microelectronic package 420 as defective or greatly reduce the reliability of microelectronic package 420 during operation.

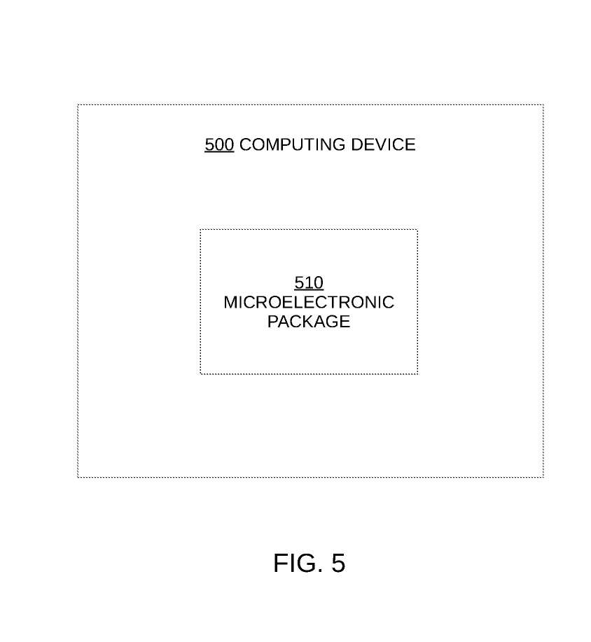

FIG. 5 illustrates a computing device in which various embodiments of the present invention can be implemented. Specifically, FIG. 5 is a block diagram of a computing device 500 with a microelectronic package 510 configured according to an embodiment of the present invention. Computing device 500 may be a desktop computer, a laptop computer, a smart-phone, a digital tablet, a personal digital assistant, or other technically feasible computing device. Microelectronic package 510 is substantially similar in configuration and operation to microelectronic packages 100 or 200, described above in conjunction with FIGS. 1-3, and may include a CPU, a GPU, an application processor or other logic device, volatile memory, such as random access memory (RAM), non-volatile memory, such as flash memory, a system-on-chip (SOC), or any other IC chip-containing device.

In sum, embodiments of the invention set forth a microelectronic package with a stiffener plate or heat spreader that has recesses formed on the edges thereof. The recesses are positioned to correspond to locations of alignment surfaces of the microelectronic package, so that overhang of the stiffener plate or heat spreader with respect to the alignment surfaces does not interfere with contact between these alignment surfaces and an alignment tool. An advantage of the above-described embodiments is that a stiffener plate or heat spreader that is sized to cover most or all of the periphery of a package substrate can be coupled to the package substrate without causing alignment issues in subsequent fabrication processes. In this way, the trade-off is reduced between greater microelectronic package stiffness and poor alignment of the microelectronic package is some fabrication steps. Consequently, a microelectronic package can be fabricated with greater stiffness and without increasing defectivity or reliability of the microelectronic package.

While the foregoing is directed to embodiments of the present invention, other and further embodiments of the invention may be devised without departing from the basic scope thereof, and the scope thereof is determined by the claims that follow.

We claim:

1. A microelectronic package, comprising:
a package substrate with at least one semiconductor die mounted thereon; and
a plate coupled to the package substrate and configured with a first recess formed in a first edge and a second recess formed in a second edge,
wherein the first edge and the second edge are formed on opposing sides of the plate.

2. The microelectronic package of claim 1, wherein the plate is in thermal contact with the at least one semiconductor die.

3. The microelectronic package of claim 1, wherein the first recess corresponds to a first alignment surface of the package substrate that is configured to contact a first surface of an alignment tool for a testing or package assembly process, and the second recess corresponds to a second alignment surface of the package substrate that is configured to contact a second surface of the alignment tool.

4. The microelectronic package of claim 1, further comprising a third recess formed in a third edge of the plate and a fourth recess formed in a fourth edge of the plate, wherein the third edge and the fourth edge are formed on opposing sides of the plate.

5. The microelectronic package of claim 1, wherein the plate comprises at least one of a stiffener plate and a heat spreader.

6. The microelectronic package of claim 1, further comprising a third recess formed in the first edge of the plate and a fourth recess formed in the second edge of the plate.

7. The microelectronic package of claim 6, wherein the first recess corresponds to a first alignment surface of the package substrate that is configured to contact a first surface of an alignment tool for a first testing or package assembly process and the third recess corresponds to a second alignment surface of the package substrate that is configured to contact a second surface of an alignment tool for a second testing or package assembly process.

8. The microelectronic package of claim 6, wherein the first recess and the second recess are disposed substantially opposite each other, and the third recess and the fourth recess are disposed substantially opposite each other.

9. The microelectronic package of claim 6, wherein the plate comprises a substantially rectangular plate, and each of the first recess, the second recess, the third recess, and the fourth recess is disposed closer to a corner of the rectangular plate than to a center point of any one of the edges.

10. The microelectronic package of claim 1, wherein the plate includes a central opening that corresponds to a keep out area of the package substrate.

11. The microelectronic package of claim 1, wherein a width of the plate is equal to or greater than a corresponding width of the package substrate.

12. A computing device, comprising:
a microelectronic package that includes:
a package substrate with at least one semiconductor die mounted thereon; and
a plate coupled to the package substrate and configured with a first recess formed in a first edge and a second recess formed in a second edge,
wherein the first edge and the second edge are formed on opposing sides of the plate.

13. The computing device of claim 12, wherein the plate is in thermal contact with the at least one semiconductor die.

14. The computing device of claim 12, wherein the first recess corresponds to a first alignment surface of the package substrate that is configured to contact a first surface of an alignment tool for a testing or package assembly process and the second recess corresponds to a second alignment surface of the package substrate that is configured to contact a second surface of the alignment tool.

15. The computing device of claim 12, further comprising a third recess formed in a third edge of the plate and a fourth recess formed in a fourth edge of the plate, wherein the third edge and the fourth edge are formed on opposing sides of the plate.

16. The computing device of claim 12, wherein the plate comprises at least one of a stiffener plate and a heat spreader.

17. The computing device of claim 16, further comprising a third recess formed in the first edge of the plate and a fourth recess formed in the second edge of the plate.

18. The computing device of claim 17, wherein the first recess corresponds to a first alignment surface of the package substrate that is configured to contact a first surface of an alignment tool for a first testing or package assembly process and the third recess corresponds to a second alignment surface of the package substrate that is configured to contact a second surface of an alignment tool for a second testing or package assembly process.

19. The computing device of claim 12, wherein a width of the plate is equal to or greater than a corresponding width of the package substrate.

20. A system, comprising:
an alignment tool having a first alignment surface and a second alignment surface; and
a microelectronic package that includes:
a package substrate with at least one semiconductor die mounted thereon; and
a plate coupled to the package substrate and configured with a first recess formed in a first edge and a second recess formed in a second edge,
wherein the first edge and the second edge are formed on opposing sides of the plate, and
the first alignment surface contacts a portion of the package substrate that corresponds to the first recess and the second alignment surface contacts a portion of the package substrate that corresponds to the second recess.
